(19) United States
(12) Patent Application Publication
(10) Pub. No.: US 2010/0148772 A1
(43) Pub. Date: Jun. 17, 2010

(54) Method and apparatus for measuring electric currents

(76) Inventors: Jan Wenske, Radbruch (DE); Jürgen Scheffel, Norderstedt (DE); Ulf Kobisch, Hamburg (DE)

Correspondence Address: Friedrich Kueffner, Suite 910, 317 Madison Avenue, New York, NY, 10017, US

(21) Appl. No.: 12/592,582

(22) Filed: Nov. 27, 2009

(30) Foreign Application Priority Data
Nov. 28, 2008 (DE) 10 2008 061 006.2

(51) Int. Cl. G01R 33/02

(52) U.S. Cl. 324/259

(57) ABSTRACT

A method and an apparatus for measuring electric currents include at least one sensor for measuring the magnitude of the field strength depending on the current. The current to be measured is conducted past the sensor at least partially with oppositely directed directional components at the sensor. At least one magnetic field sensor can be used as a sensor.

### BACKGROUND OF THE INVENTION

1. Field of the Invention

The present invention relates to a method of measuring electric currents, wherein a magnetic field strength is measured which depends on the magnitude of the current being measured by using at least one sensor.

The present invention also relates to an apparatus for measuring electric currents which includes at least one sensor for determining a magnetic field strength which depends on the magnitude of the current.

2. Description of the Related Art

Methods and apparatus of the above-described type are known already in the art in the form of different embodiments. In particular, in a galvanically separate current measurement in the range of high currents, typically with values of several 100 Ampere, in the past it has not been possible to meet all requirements with respect to high sensitivity and susceptibility to trouble, while simultaneously being of compact to the construction. A typical field of application for such current measurements are direct current and/or alternative current measurements in converting applications.

It is the object of the present invention to improve a method of the above-described type in such a way that a high sensitivity of the current measurement is obtained.

### SUMMARY OF THE INVENTION

In accordance with the present invention, the current to be measured is at least partially conducted past the sensor on essentially oppositely located sides of the sensor with at least partially oppositely directed components.

Another object of the present invention is to further develop an apparatus of the type described above in such a way that a high sensitivity is obtained while simultaneously a high accuracy is obtained.

In accordance with the present invention, at least portions of a conductor for conducting the electric current extend along essentially oppositely located sides of the sensor in such a way that the portions are arranged one behind the other at least in one component of a flux direction of the electric current.

By conducting the current in such a way that the current to be measured is aligned on opposite sides of the sensor with opposite directional components, a superimposition in the same direction takes place in the area of the sensor of the respectively generated magnetic fields. Consequently, there is in particular no compensation of field components which would be generated if the current were conducted in the same direction past oppositely located sides of the sensor and which would lead to a significant reduction of the sensitivity.

As a result of the superimposition of the field components in the same direction it is especially possible to omit a core of a ferromagnetic material which would bundle the field to be measured. This has the significant advantage that the sensor is not subject to saturation effects. Such saturation can be created, for example, if in connection with converters a final power stage is operated in short circuit. Also, by avoiding saturation effects, self-heating of the sensor is avoided. A sensor temperature which would limit the capability of operation of the sensor by exceeding a maximum permissible operational temperature, would therefore be determined essentially only by the prevailing ambient conditions and not by a negative output in the area of the sensor. Such a negative output can be caused, for example, by magnetic reversal loses.

Magnetic field sensors, for example, Hall elements, and magnetoresistive elements can be used as sensors.

In accordance with an embodiment, the current measurement is carried out in the area of a current rail.

A particularly high sensitivity can be achieved by providing the current rail adjacent to the sensor with a U-shaped or L-shaped configuration.

In accordance with another embodiment, it is also possible to carry out a current measurement in the area of a cable.

A further increase of the sensitivity can be achieved by winding the cable at least partially around the sensor.

The functional security can be increased by carrying out at least one sensor test.

It is particularly intended to carry out the sensor test by using at least one coil. The decisive aspect is the generation of a magnetic field.

Another increase of the functional security can be achieved by monitoring the temperature in the area of the sensor.

Decreases of the measuring accuracy by stray fields can be avoided by carrying out an electromagnetic screening in the area of the sensor. This is particularly useful when there are interference fields or adjacent conductors.

A particularly simple assembly and disassembly is achieved by securing a sensor housing which positions the sensor with respect to space by using at least one cable binder. Also possible are the use of screws or clamps or glued connections.

The various features of novelty which characterize the invention are pointed out with particularity in the claims annexed to and forming a part of the disclosure. For a better understanding of the invention, its operating advantages, specific objects attained by its use, reference should be had to the drawing and descriptive matter in which there are illustrated and described preferred embodiments of the invention.

### BRIEF DESCRIPTION OF THE DRAWING

In the drawing:

FIG. 1 is a side view of a current rail with a U-shaped conductor configuration in the area of a mounting location for a current sensor;

FIG. 2 is a modified embodiment as compared to FIG. 1 with a curved configuration of the current rail and with a sensor plate assigned to the current rail;

FIG. 3 is a principal illustration for demonstrating the manner of operation;

FIG. 4 is a perspective view of a current sensor with magnetic field sensor which is placed in a support section of a current rail;

FIG. 5 is a perspective exploded view of the sensor of FIG. 4 without the support section which receives the sensor;

FIG. 6 is an illustration of a current rail with L-shaped conductor configuration in the area of a space for mounting the current sensors;

FIG. 7 is a perspective illustration of a current sensor arranged in the area of a current rail with an integrated sensor testing capability with the use of air coils; and

FIG. 8 is a perspective side view of a guide element for positioning the cable in the area of the sensor.

### DETAILED DESCRIPTION OF THE INVENTION

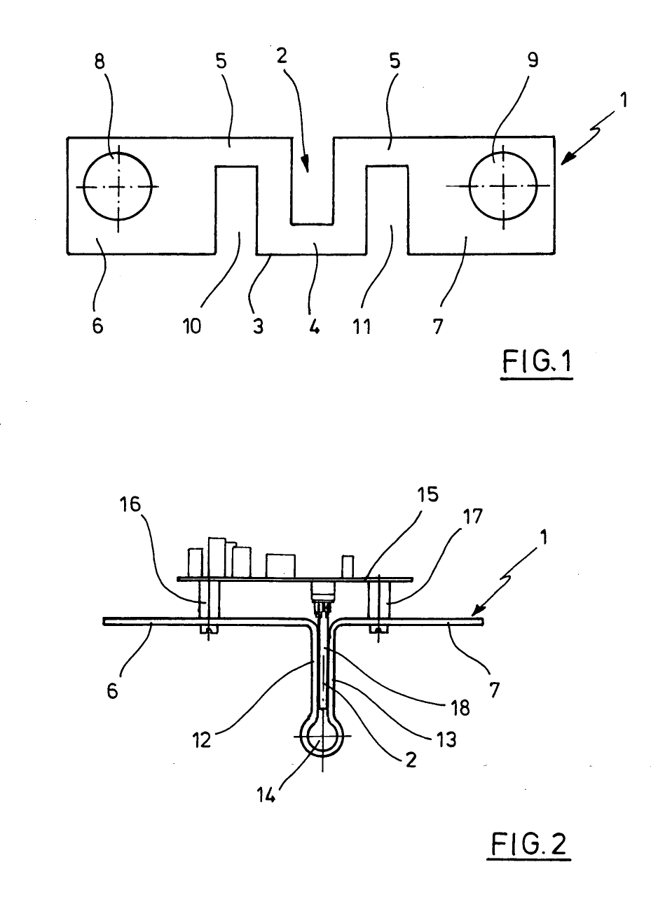

FIG. 1 is a side view of a current rail 1 which is provided in the area of a sensor pick-up 2 with a U-shaped conductor configuration 3. The ends of the conductor configuration 3 facing away from the basic leg 4 are typically connected through transverse webs 5 to main areas 6, 7 of the current rail 1. The main areas 6, 7 typically have recesses 8, 9 for fastening the current rail 1 in the area of counter elements, not shown. Side legs of the U-shaped conductor configuration 3 are separated from the principal areas 6, 7 by incisions 10, 11 in such a way that a connection is realized only from the transverse webs 5. In the case of such current rails 1 the sensor receiving space 3 and the incisions 10, 11 can be produced, for example, in the case of greater material thicknesses by milling cutting or in the case of smaller material thicknesses by bending in the area of the current rail 1. In the case of longer current rails 1, typically the transverse webs 5 are made correspondingly longer.

FIG. 2 shows an embodiment which is modified as compared to FIG. 1 for making available a current supply in the area of the sensor pick-up 1 which electrically corresponds to the construction of FIG. 1. The main areas 6, 7 of the current rails 1 are in this case curved into transverse legs 12, 13 which extend preferably parallel to each other and define the pick-up space 2 of the sensor. The sensor pick-up space 2 is located between the transverse legs 12, 13 in the area of a homogenous field space. The transverse legs 12, 13 extend into each other through a curved bending area 14, wherein the bending area 14 has a suitable bending radius in order to take into consideration the material properties of the current rail 1. Typically, the current rail 1 is of copper or a copper alloy.

FIG. 2 also shows the arrangement of a sensor plate 15 in the area of the current rail 1. The sensor plate 15 is in this case secured by support elements 16, 17 in the area of the recesses 8, 9. A sensor 18 extends into the area of the sensor pick-up space 2, wherein the sensor 18 is constructed as a magnetic field sensor.

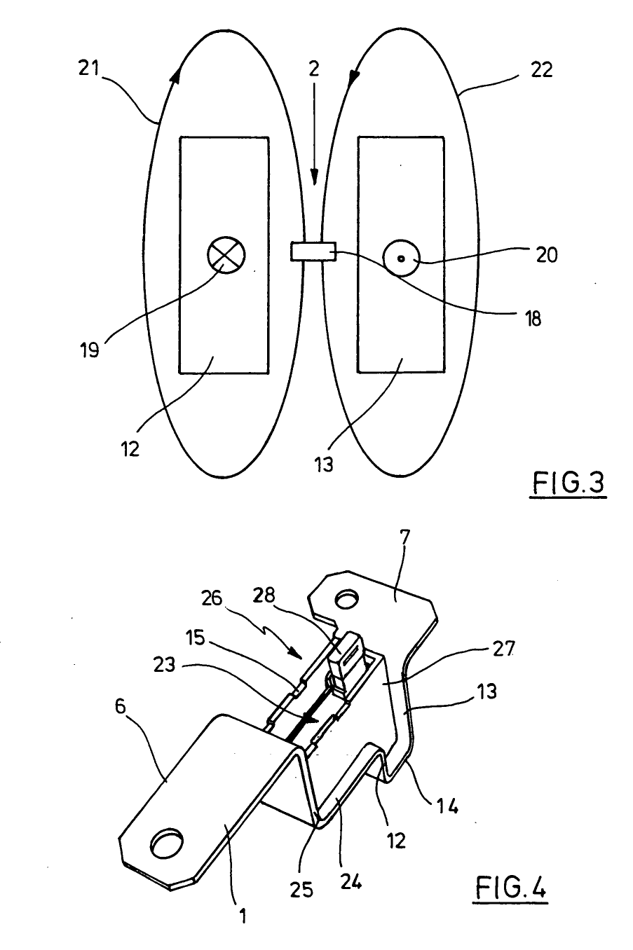

FIG. 3 is a schematic illustration for showing the manner of operation of the sensor arrangement. FIG. 3 corresponds, for example, to a cross-section through the sensor pick-up space 2 defined by the transverse legs 12, 13. Opposite current flux directions 19, 20 as well as typical field line patterns 21, 22 of the magnetic field strength are in the area of the transverse legs 12, 13. It can be seen that the field line patterns in the area of the sensor pick-up space 2 are superimposed in the same direction and, consequently, increase the field strength and the sensitivity of the measurement.

FIG. 4 shows an embodiment in which the sensor plate 15 supporting the sensor 18 is arranged in a sensor housing 23 supported by a specially shaped current rail 1. In this case, the current rail 1 is constructed similar to the principle of manufacture according to the embodiment of FIG. 2 which, however, has a different bending contour from that of FIG. 2. In particular, the transverse leg 12 extends not parallel to the entire extension of the transverse leg 13, but starting from the bending area 14 only along a portion of the transverse leg 13.

In the area of its extension in the bending area 14, the transverse leg 12 is bent into a plane which extends essentially parallel to a plane starting from the principal areas 6, 7 of the current conductor 1 and is held at this plane. This makes available a support leg 24 which extends through a further bent portion into a contact leg 25 which, in turn, is adjacent through a bent portion to the main area 6 of the current rail 1. A partial area of the transverse leg 13, the support leg 24 and the contact leg 25 consequently, define a housing pick-up space 26 for the sensor housing 23.

The current rail 1 and the sensor or the sensor housing 23 are in this embodiment constructed as a unit because of the manner in which the embodiment is secured. The geometric configuration of the current rail 1 and the spatial arrangement of the sensor relative to the current rail 1 influence the measurement, on the one hand, but are constant because of the fixed mechanical relationship, on the other hand. Therefore, the sensor can be calibrated easily and simply. During the entire measurement, the position of the sensor or the position of the sensor plate 15 relative to the current rail is constant.

A connecting element 28 is supported on the sensor plate 15 through a plug-connection 27. The connecting element 28 has in the illustrated embodiment an insertion opening with contacts for a flat band cable, not shown. For example, connections for a supply voltage, a signal output, an output reference as well as for a trigger signal for carrying out a self test can be present. It is optionally also possible to provide a connection for the output signal of the internal temperature sensors.

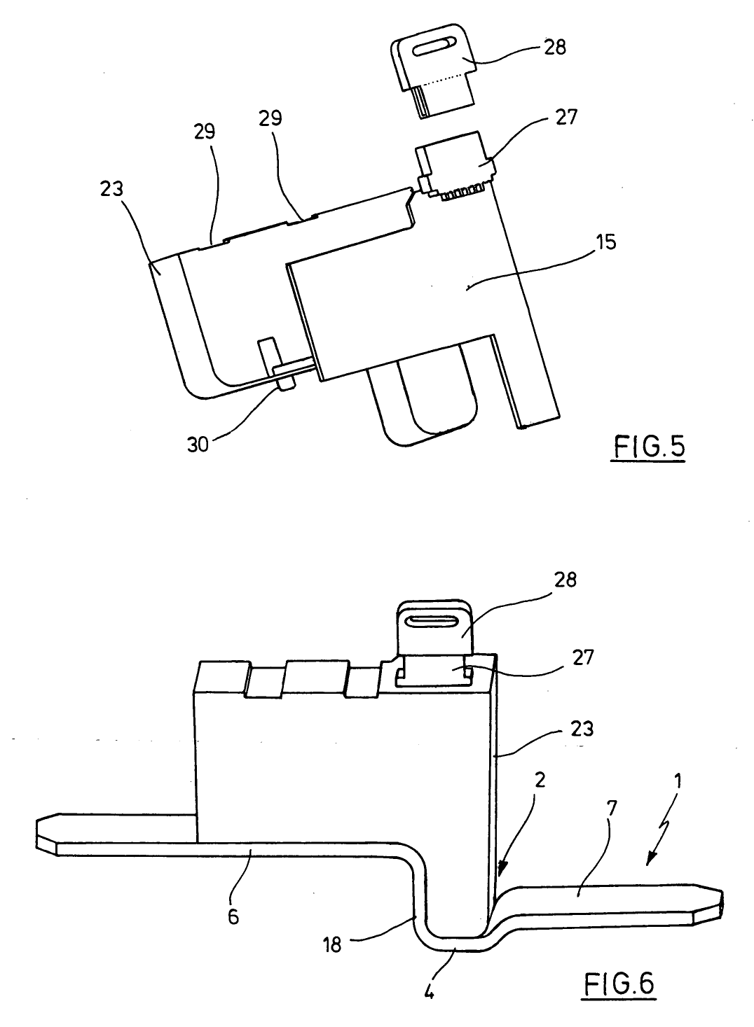

FIG. 5 shows in an exploded view the sensor housing 23 with the sensor plate 15 being removed and the connecting element 28 pulled out of the plug connector 27. It can be seen that the sensor housing 23 has recesses 29 which serve for positioning cable binders, not shown, which fix the sensor housing 23 in the area of the housing pick-up space 26. A lateral fixation of the sensor housing 23 in the area of the housing pick-up space 26 is supported, for example, by a housing protrusion 30 which can be inserted into a corresponding recess in the area of the support leg 24.

FIG. 6 shows a configuration of the current rail 1 which is modified as compared to the embodiments of FIGS. 1 and 4. In this case, an L-shaped contour of the current rail 1 is provided in the area of the sensor pick-up space 2. However, the simplification of the constructions according to FIG. 6 as compared to the construction according to FIG. 1 or 4 has the result that it is not possible to achieve the full sensitivity of the arrangement according to FIG. 1 or FIG. 4.

However, the current conducting configuration according to the present invention adjacent the sensor is not limited to current rails 1, but can also be used in current configurations based on cables or conductors. By using such cables or conductors, it is possible to realize a multiple guidance of the current past the sensor 18 and to achieve any further increase of the sensitivity as a result. This embodiment will be discussed further when the embodiment of FIG. 8 is being discussed.

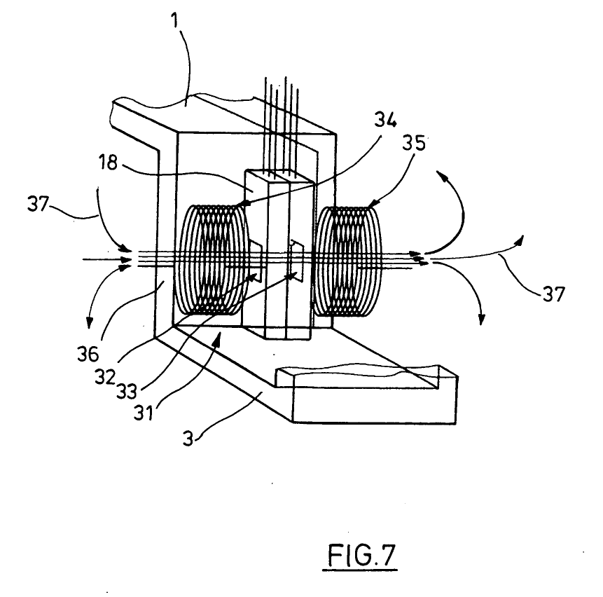

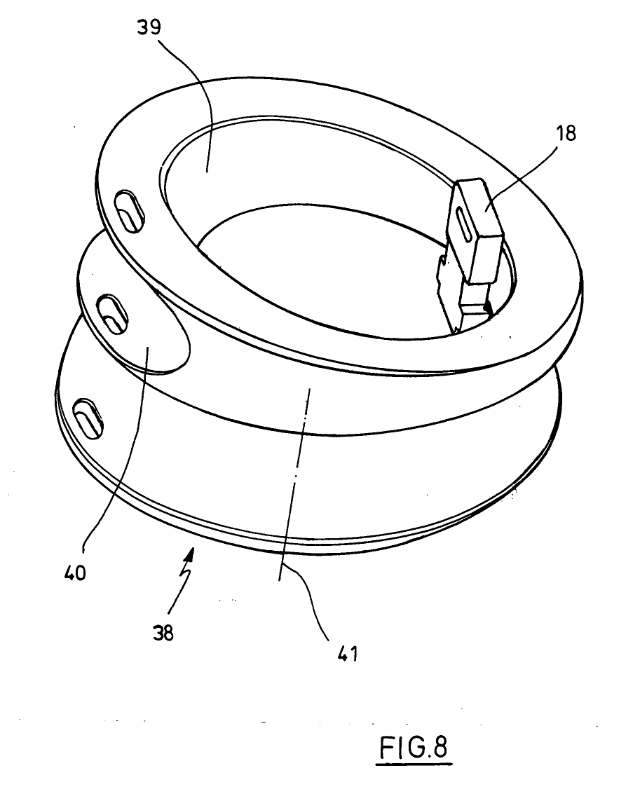

FIG. 7 shows the use of a sensor 18 with an assigned test device 31. In the area of the sensor 18, two sensor elements 32, 33 are arranged which are constructed, for example, as Hall elements. Coils are positioned respectively adjacent the magnetic field sensors 32, 33, the coils 34, 35 are constructed, for example, as air coils. By providing the two coils 34, 35 a field 36 is produced in the area of the magnetic field sensors 32, 33. A stray field 37 is produced in the area of the Hall elements 32, 33 facing away from the surrounding areas of the coils 34, 35.

By using the coils 34, 35 it is made possible that the sensor function, particularly the measurement of the magnetic field strength, can be tested by means of the magnetic field sensor 32, 33. It is possible to generate a voltage or current output signal which is proportional to the magnetic field strength, so that testing of the sensor 18 can be carried out independently of an actual current flux in the current rail 1. A positioning of the coils 34, 35 typically takes place in such a way that the Hall elements are located in the area of the greatest flux density of the coils 34, 35.

An excitation of coils 34, 35 can be effected, for example, directly or through an induced control signal. An output signal proportional to the excitation current of the sensor 18 results in a functioning sensor 18; in the case of deviations, it can be concluded that there is a malfunction.

In accordance with a simplified sensor test, it is only tested whether an excitation of the coils 34, 35 results at all in a generation of an output signal of the sensor 18. The use of coreless air coils 34, 35 avoids a change of the magnetic measuring circuit of the sensor system.

A return effect on the sensor function is therefore excluded during normal measuring operation. If coils 34, 35 are used with a relatively high number of windings, it is possible to use low excitation currents, for example, smaller than 1 Ampere, in order to test the sensor 18 in the fully intended control range.

The use of the testing device 31 according to FIG. 7 can also be utilized for other applications. For example, it is possible to carry out an excitation of the coil arrangement when switching on the supply voltage. An evaluation device is used for testing whether the given threshold values for the sensor output signal has been reached and is possibly stored. When the predetermined threshold value has been reached, the sensor is released. When the threshold value is not reached, the sensor is driven by an offset generated by the control into a positive or negative control limit. Malfunctions of the sensor when the sensor is switched on can be securely detected as a result.

When using the sensor arrangement in conjunction with output end stages, such a control of the sensor can be detected at the control limit as a critical operational state, which, for example, leads to a rapid locking of the output end stages generated by the control. A converter is in this manner automatically converted into a secure state when the unit is switched on with defective current sensors 18.

In the area of the sensor plate 15 it is possible to arrange a temperature sensor and it is moreover possible to monitor the supply voltage for the magnetic field sensors 32, 33. Also in this case, it is possible, when a predetermined threshold value has been exceeded; it is possible to drive, as previously already explained by using an offset into a positive or negative control limit.

A significant advantage of the monitoring concept described above is that the control does not require any additional input channels. With respect to its connections, the sensor 18 according to the present invention is compatible with conventional sensors without the monitoring function.

A use of the sensor 18 can take place in the area of the measurement of direct currencies as well as in the area of the measurement of alternating currents. Measurements of currents having a frequency of up to 100 kHz can be realized without problems.

FIG. 8 shows a guide element 38 for positioning a cable, not shown, wherein the current flow in the area of the cable is to be measured through the sensor 18. The guide element 28 has a sleeve-like or ring-like basic contour, wherein a support section 40 for the cable extends in a wall 39 of the guide element 38 on the outer side of the guide element 38. The cable extends similar to the pitch of a thread. Typically the thread-like support section 40 extends approximately once around the outer circumference of the guide element 38. When considering these geometric relationships, the guide element has in the direction of a longitudinal axis 41 a different height at different circumferential positions as predetermined by the configuration of the support section 40.

In contrast to the illustrated simple winding of the sensor 18 with a corresponding cable, it is basically also possible to provide for other multiple windings of the cable. The guide element 38 would then be constructed with a higher dimension while the cable thickness in the longitudinal direction 48 is the same, or, when the cable thickness is smaller, the guide element 38 would have a support section 40 with several windings. Also, it is conceivable to realize only a partial winding of the sensor and to deflect the cable only in accordance with a U-shape or L-shape configuration.

While specific embodiments of the invention have been shown and described in detail to illustrate the inventive principles, it will be understood that the invention may be embodied otherwise without departing from such principles.

We claim:

1. A method of measuring electric currents, the method comprising measuring a magnetic field strength depending on the magnitude of the current to be measured by using at least one sensor, further comprising conducting the current to be measured on essentially oppositely located sides of the sensor with at least partially oppositely directed components past the sensor.

2. The method according to claim 1, comprising carrying out the current measurement in an area of a current rail.

3. The method according to claim 2, comprising providing the current rail adjacent to a magnetic field sensor with a U-shaped section.

4. The method according to claim 1, comprising carrying out a current measurement in an area of a cable.

5. The method according to claim 4, comprising moving the cable at least once past the magnetic field sensor.

6. The method according to claim 1, comprising carrying out at least one sensor test.

7. The method according to claim 6, comprising carrying out the sensor test by using at least one coil.

8. The method according to claim 1, comprising monitoring the temperature in an area of the sensor.

9. The method according to claim 1, comprising carrying out an electromagnetic screening in the area of the sensor.

10. The method according to claim 1, comprising spatially fixing sensor housing which positions the sensor by using at least one cable binder.

11. An apparatus for measuring electric currents, the apparatus comprising at least one sensor for determining the magnitude of a field strength which is dependant on the magnitude of the current, wherein at least one area of a conductor for conducting the electric current extends along essentially oppositely located sides of the sensor such that the areas are located one behind the other at least in a component of a flux direction of the electric current.

12. The apparatus according to claim 11, wherein the sensor is a magnetic field sensor.

13. Apparatus according to claim 11, wherein two sensor elements are used such that a differential evaluation of a temperature dependency of the sensor output signal is at least predominantly compensated.

14. The apparatus according to claim 11, wherein the sensor is arranged in an area of a current rail.

15. The apparatus according to claim 11, wherein the current rail has adjacent the sensor a U-shaped profile.

16. The apparatus according to claim 11, wherein the sensor is mounted in an area of a cable.

17. The apparatus according to claim 16, wherein the cable is at least partially wound around the sensor.

18. The apparatus according to claim 11, wherein the sensor has at least one testing device.

19. The apparatus according to claim 18, wherein the testing device comprises at least one coil.

20. The apparatus according to claim 11, wherein the sensor is provided with temperature monitoring.

21. The apparatus according to claim 11, wherein the sensor has at least one electromagnetic screening.

22. The apparatus according to claim 11, wherein a sensor housing for holding the sensor is supported by at least one cable binder in an area of the conductor.

23. The apparatus according to claim 11, the apparatus comprising, for achieving in converter applications a fail-safe behavior without requiring additional cable means for controlling the sensor system by stopping the positive or negative control limit of the sensor system.
